(19) United States
(12) Patent Application Publication
(10) Pub. No.: US 2004/0193301 A1
(43) Pub. Date: Sep. 30, 2004

(54) Inventory control via a utility bill of materials (BOM) to minimize resource consumption

(76) Inventors: Chen-Lin Chao, Hsin-Chu (TW); Wei-Kuo Yen, Hsin-Chu (TW); Jiunh-Yih Lee, Hsin-Chu (TW)

Correspondence Address: TAIWAN SEMICONDUCTOR MANUFACTURING CO., LTD., C/O SLATER & MATSIL, L.L.P., 17950 PRESTON ROAD, SUITE 1000, DALLAS, TX, 75252, US

(21) Appl. No.: 10/403,491

(22) Filed: Mar. 31, 2003

(51) Int. Cl. G06F 19/00

(52) U.S. Cl. 700/106; 700/99

(57) ABSTRACT

System and method for controlling the use of control wafers in a semiconductor fabrication line with load balancing and resource minimization. A preferred embodiment comprises a control wafer manager (for example, control wafer manager 605) and an inventory manager (for example, inventory manager 630). The control wafer manager uses a fabrication process dependency graph (for example, fabrication process dependency graph 407) to help determine where a control wafer may be able to go after it has completed its current process step. The inventory manager uses available inventory at each process step to assist in the decision process. Finally, a check-in process is used to ensure accurate inventory control.

### TECHNICAL FIELD

The present invention relates generally to a system and method semiconductor fabrication, and more particularly to a system and method for controlling the use of control wafers to minimize resource consumption in a semiconductor fabricate on line.

### BACKGROUND

To create an integrated circuit (IC) or a semiconductor device for that matter, on a semiconductor wafer (or simply, wafer), a series of steps must be followed. For example, a series of steps may include: clean, photo, deposition, sputter, etch, polish, and grind. Additionally, several steps may include several sub-steps. In order for the IC to be created successfully, each step in the fabrication process must execute successfully.

Since each step in the fabrication process is important to the quality of the final product, each step requires monitoring to ensure that the step is being performed in a manner that is consistent with specifications. One commonly used way to monitor the various manufacturing steps is to examine the wafers as they complete each step. After each fabrication step, the wafers (perhaps all wafers or a percentage of the total number of wafers) are examined. If the examined wafers are of sufficient quality, the wafers are allowed to proceed to the next step in the fabrication process. If the wafers are not of sufficient quality (i.e., the fabrication process step did not perform as expected), then the wafers may be discarded and the fabrication process is restarted with a new batch of wafers.

Another commonly used way to monitor the various manufacturing steps is to insert what is known as a control wafer(s) into the manufacturing process. The control wafer undergoes the fabrication step just like the wafers and after the fabrication step completes, the control wafer can be extracted and examined. Again, if the control wafer displays that the fabrication step executed well, the wafers are permitted to go to the next step of the fabrication process. If the control wafer displays that the fabrication step did not execute well, then the wafers may need to be discarded and the fabrication process restarted. A control wafer can be used for a single step in the fabrication process or it can be used for several steps. When a control wafer is used in several fabrication steps, there may be an order of fabrication steps that needs to be followed to ensure that the control wafer is providing an accurate picture of the fabrication process steps. For example, it would not be feasible for the control wafer to be etched in an etching step and then polished in a polishing step while the reverse could be correct.

One disadvantage of the prior art is a relatively large number of control wafers is required. The large number of control wafers leads to waste and hence, higher operating costs.

A second disadvantage of the prior art is that since a new control wafer is used for each step of the fabrication process, it is possible for shortages and excesses of control wafers to occur at different fabrication process steps. Therefore, if there is a shortage of control wafers at a particular fabrication process step, the fabrication needs to either stop to wait for the delivery of additional wafers or the fabrication proceeds with insufficient quality control. Neither option is desirable.

A third disadvantage of the prior art is that if the actual wafers are used to determine the quality of the fabrication steps, then the examination of the wafers may result in damage or contamination of the wafers. In either case, the wafer is no longer usable.

### SUMMARY OF THE INVENTION

These and other problems are generally solved or circumvented, and technical advantages are generally achieved, by preferred embodiments of the present invention which provides a system and method for using control wafers in a semiconductor fabrication process that minimizes resource consumption.

In accordance with a preferred embodiment of the present invention, a method for controlling the use of a control wafer comprising registering the control wafer a first time, using the control wafer, registering the control wafer a second time, and selecting a second use for the control wafer

In accordance with another preferred embodiment of the present invention, a method for minimizing control wafer usage in a fabrication process of a plurality of individual process steps comprising registering a control wafer a first time, using the control wafer, registering the control wafer a second time, determining a list of possible subsequent process steps, and selecting a subsequent process step from the list of possible subsequent process steps

In accordance with a preferred embodiment of the present invention, a system for controlling the use of a control wafer comprising a control wafer manager with circuitry to maintain an inventory of fresh control wafers, an inventory of reclaimed control wafers, and a fabrication process dependency graph, and an inventory manager coupled to the control wafer manager, the inventory manager containing circuitry to maintain an inventory of control wafers used in a fabrication process

An advantage of a preferred embodiment of the present invention is that a single control wafer may be used to test several different fabrication process steps, therefore the total number of control wafers needed for a fabrication line is reduced, resulting in significant savings.

A further advantage of a preferred embodiment of the present invention is that a control wafer management system is provided to help ensure that shortages and excesses of control wafers are certain fabrication process steps do not occur.

Yet another advantage of a preferred embodiment of the present invention is that the present invention may be implemented with very little to no additional hardware investment. Therefore, the savings in reducing the number of control wafers is not mitigated by significant implementation costs.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 is a flow diagram depicting a typical series of fabrication steps that a semiconductor wafer undergoes during the fabrication of an integrated circuit on the wafer;

FIG. 2 is a table listing several main types of control wafers;

FIG. 3 is a diagram depicting a prior art system for managing the use of control wafers;

FIG. 4 is a diagram depicting a second prior art system for managing the use of control wafers, wherein a single control wafer may be used at more than one fabrication step;

FIG. 5 is a flow diagram depicting a prior art BOM (bill of materials) for a single fabrication step;

FIG. 6 is a diagram depicting a control wafer management system with an ability to balance control wafer inventory and to minimize control wafer usage, according to a preferred embodiment of the present invention;

FIG. 7 is a flow diagram depicting a BOM for a single fabrication process step, wherein the BOM has support for balanced control wafer inventory and minimized control wafer usage, according to a preferred embodiment of the present invention;

FIG. 8 is a diagram depicting a relationship between a BOM and a fabrication process dependency graph, according to a preferred embodiment of the present invention; and

FIG. 9 is a diagram depicting an exemplary fabrication process control flow and the flow of control wafers in the fabrication process, according to a preferred embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely a semiconductor fabrication plant. The invention may also be applied, however, to other manufacturing situations wherein samples are made of different steps in the manufacturing process and there is a desire to minimize the number of samples needed.

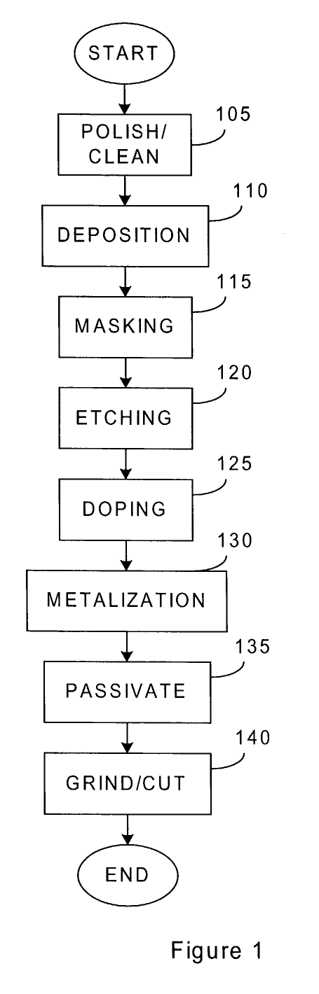

With reference now to FIG. 1, there is shown a flow diagram illustrating a typical series of fabrication process steps that a semiconductor wafer (or simply, wafer) undergoes during the fabrication of integrated devices on the wafer. After the creation of a silicon ingot, individual wafers are cut from the ingot and the polished and clean (block 105) to a mirror-like finish. After polishing and cleaning, the wafer is exposed to ultra-pure oxygen in diffusion furnaces (block 110). This is known as thermal oxidation or deposition.

After deposition, a mask is applied on the wafer (block 115). The mask protects portions of the wafer while permitting work to proceed on another portion. This may be followed by etching (block 120) wherein portions of the wafer are removed when the wafer is exposed to either a chemical solution or plasma. Doping (block 125) is the introduction of atoms with more or less electrons than silicon. Doping alters the electrical characteristics of the silicon. The deposition, masking, etching, and doping steps may be repeated multiple times until all desired active devices are formed.

Once the active devices are formed, the active devices are interconnected via a series of metal conductors formed by a series of depositions of metal and dielectric films (block 130). Finally, a passivation (non-conductive, protective) layer is laid on top of the wafer (block 135). The individual integrated circuits (IC) are then cut from the wafer (block 140) and packaged for use. Note that FIG. 1 displays the fabrication process steps for a typical fabrication process and that different fabrication process technologies may have different process steps.

Each step of the fabrication process discussed in FIG. 1 involves a relatively complex series of events. To ensure that the process steps are occurring with desired results, the process steps are monitored and well regulated. Since the fabrication occurs on a microscopic scale and typically in clean-rooms, it is difficult to physically observe the fabrication steps. Instead, the results of the fabrication steps (the wafers) are examined to determine the fabrication steps are producing wafers meeting specified parameters.

However, the wafers may be damaged and/or contaminated during the physical examination. Therefore, it may be desirable to use sacrificial wafers whose purpose is to measure the performance of the fabrication steps. These sacrificial wafers are commonly referred to as control wafers. Control wafers are placed along side the wafers and undergo the same fabrication step as the wafers. At the completion of the fabrication step, the control wafers can be removed and examined. The use of the control wafers leaves the wafers untouched and hence free from damage and/or contamination from the inspection.

After the examination, the control wafers are either discarded (if they were damaged or contaminated during the examination or if they have undergone a sequence of fabrication steps that prevents their further use) or they are placed in inventory for future use. Note that depending on the fabrication process steps that a particular control wafer has undergone, it may be prevented from being used in certain fabrication process steps. For example, if the particular control wafer has undergone a passivation layer application step, then the particular control wafer may not be usable in an etching step.

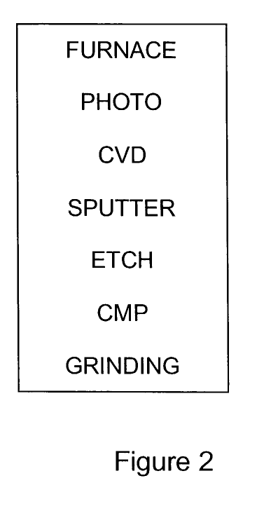

With reference now to FIG. 2, there is shown a table illustrating several main types of control wafers, according to a preferred embodiment of the present invention. Initially, a control wafer is a blank, unprocessed silicon wafer, like the wafers used in production. These blank wafers may then be designated into one of several different types. According to a preferred embodiment of the present invention, the different types of control wafers may be, but are not limited to: furnace control wafer, photo control wafer, chemical-vapor deposition (CVD) control wafer, sputter control wafer, etch control wafer, chemical-mechanical polish (CMP) control wafer, and grinding control wafer. It is possible for control wafers of a certain type to be converted (or downgraded) to a different type. However, not all control wafer types can be converted to all other types. For example, a grinding control wafer most likely cannot be converted into a photo control wafer, while a photo control wafer may be converted into a grinding control wafer.

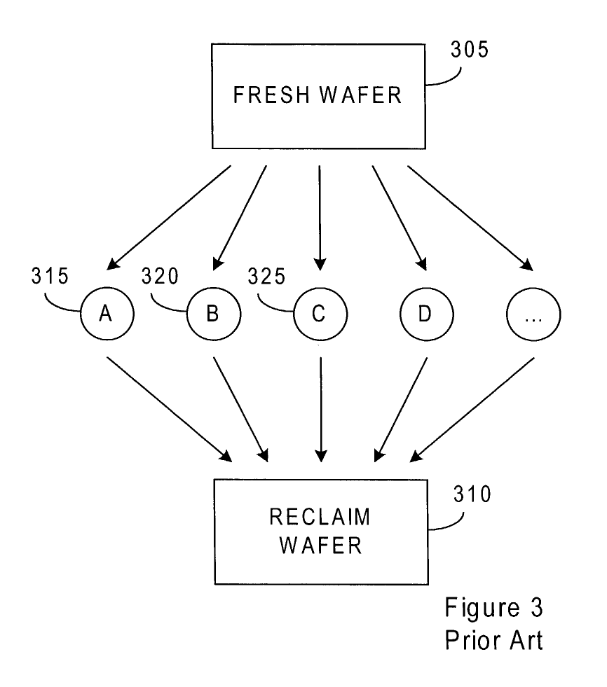

With reference now to FIG. 3, there is shown a diagram illustrating a prior art system for managing the use of control wafers. Fresh control wafers are stored in a fresh control wafer inventory 305 where they remain until needed. Control wafers that have undergone a fabrication process step are stored in a reclaim wafer inventory 310 where they remain until scrapped (destroyed). Lettered circles (for example, circle A 315 and circle B 320) represent distinct fabrication process steps.

A life cycle of a control wafer may be as follows: The control wafer, after being cut from a silicon ingot and being polished, is stored in the fresh wafer inventory 305. When needed, the control wafer is removed from the fresh wafer inventory 305 and provided to a fabrication process step, such as one represented by circle A 315. After undergoing the fabrication process step, the control wafer is examined, results noted, and then placed in the reclaim wafer inventory 310.

Note that this control wafer management system is simplistic and results in the expenditure of a large number of control wafers since a single control wafer is used per fabrication process step. A control wafer management system implemented as displayed in FIG. 3 would have a high operating cost and would be quite inefficient.

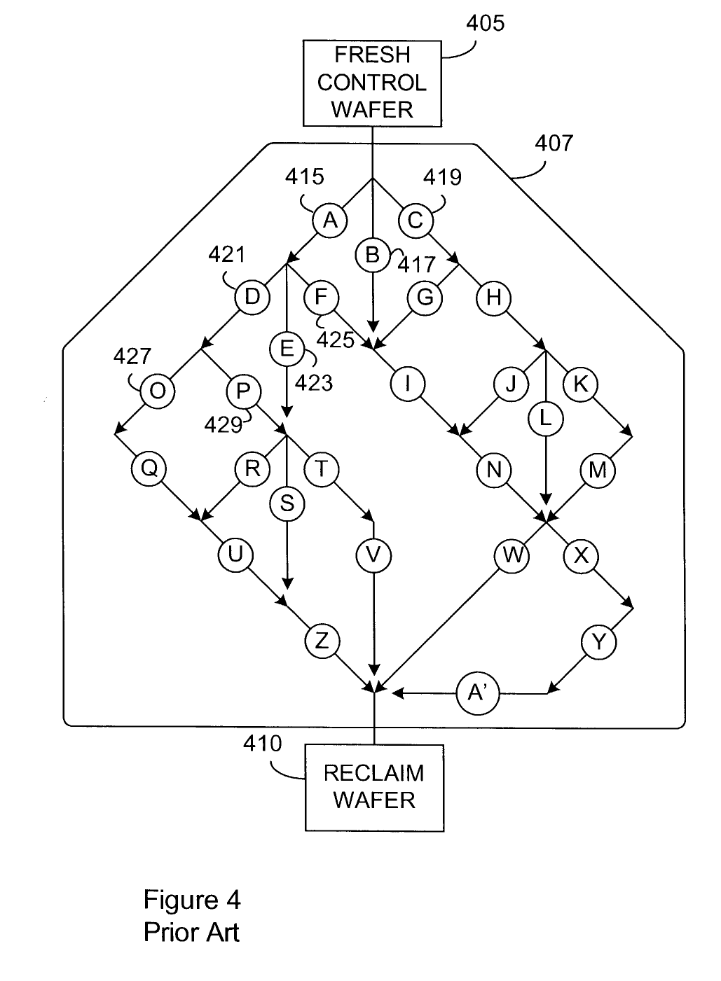

With reference now to FIG. 4, there is shown a diagram illustrating a second prior art system for managing the use of control wafers, wherein a single control wafer may be used at more than one fabrication process step. Similar to the control wafer management system displayed in FIG. 3, the control wafer management system displayed in FIG. 4 features a fresh control wafer inventory 405 and a reclaim wafer inventory 410. However, rather than simply using a control wafer for a single step in the fabrication process, the control wafer management system uses a fabrication process dependency graph 407 to permit the reuse of control wafers.

A fabrication process dependency graph is a fabrication process dependent graph that displays relationships between different steps in a fabrication process. For example, the fabrication process dependency graph can display the fact that if a control wafer has undergone a certain fabrication process step, then the control wafer may be used again in certain other fabrication process steps, but not all other fabrication process steps.

As displayed in FIG. 4, the fabrication process dependency graph 407 displays one possible set of relationships for a particular fabrication process. Note that a different fabrication process (or a different fabrication technology) may have a different fabrication process dependency graph that appears totally different from the dependency graph displayed in FIG. 4. As an example, the fabrication process dependency graph 407 displays that a fresh control wafer coming from the fresh control wafer inventory 405 may be used in one of three fabrication process steps: steps A 415, B 417, or C 419. Note that the fabrication process steps are represented by lettered circles. Once an initial fabrication process step is chosen for the fresh control wafer (as an example, assume that the control wafer was sent through fabrication process step A 415), then the formerly fresh control wafer can be used in one of three additional fabrication process steps: steps D 421, E 423, or F 425. Note that since the initial fabrication process step chosen was step A 415, the control wafer is not able to be used in control process steps B, C, G, H, J, K, L, or M.

As successive fabrication process steps are chosen for the control wafer, preferably randomly chosen when there is more than one choice, the control wafer can be visualized as working its way down the fabrication process dependency graph 407. Finally, the control wafer can no longer be used and is placed in the reclaim wafer inventory 410, where it will eventually be scrapped.

Note that as displayed in FIG. 4, the fabrication process dependency graph 407 may be a graphical representation of the actual fabrication process which is stored in a computer system's memory (not shown). Additionally, the fresh control wafer inventory 405 and the reclaim wafer inventory 410 may also be implemented in a computer system's memory. If the inventories are implemented in a memory, then the inventories may be configured to store a unique identifier for each control wafer in their inventory. The unique identifier can be used to locate a control wafer when the need arises to make use of the control wafer. Alternatively, the unique identifier may be replaced with a unique control wafer type identifier which does not uniquely identify each control wafer, but uniquely identifies different types of control wafers. Should such a computer based inventory be implemented, it is possible to keep control wafers at control wafer banks until they are needed.

Since each step in a fabrication process may involve the use of more than one control wafer, a commonly used way to keep track of available control wafers and to maintain an inventory is through the use of a bill of materials (BOM). A BOM may contain a series of steps and a recipe for the use of a control wafer in a single fabrication process step. The use of BOMs and BOMs themselves are widely used and are considered to be well understood by those of ordinary skill in the art of the present invention.

For each step in the manufacturing process, there can be a unique BOM. When a step in the fabrication process is chosen for a control wafer, then that control wafer is added to the unique BOM for the particular step. Then once the control wafer completes the selected step in the manufacturing process, the control wafer (or its unique identifier) is removed from the BOM. If a subsequent step has been chosen for the control wafer, then it is added to the subsequent step's BOM and the control wafer is moved to an appropriate location.

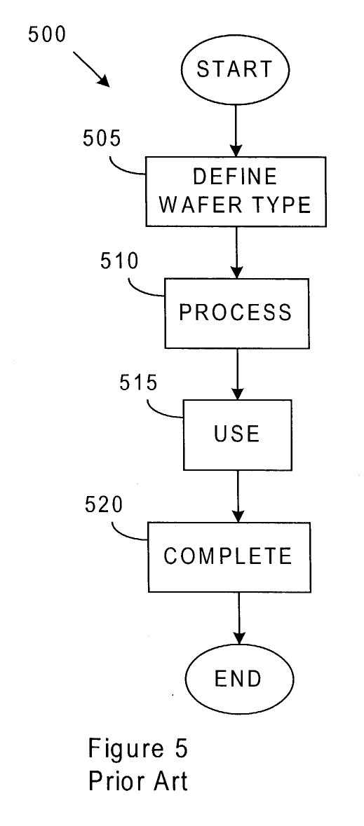

With reference now to FIG. 5, there is shown a flow diagram illustrating a prior art BOM 500 for a single fabrication process step. An initial step of the BOM 500 involves the definition of control wafer type (block 505). The control wafer type depends upon the fabrication process step the control wafer is being used in. For example, if the control wafer is being used in a photo-masking step, then the control wafer may be defined as a photo control wafer. After being defined, the control wafer is prepared for use in the fabrication process step (block 510). After the preparation processing, the control wafer undergoes the fabrication process step (block 515). Once the fabrication process step completes, the control wafer may be examined to determine the performance of the fabrication process step (block 520) and the BOM 500 completes.

While a control wafer management system with a fabrication process dependency graph as displayed in FIG. 4 permits a single control wafer to be used in multiple fabrication process steps and provides the control steps and recipes (through the use of BOMs) to control the flow of the control wafer through the fabrication process, the control wafer management system does not intelligently allocate the control wafers, possibly resulting in an abundance of control wafers at one process step while another process step is short of control wafers. Additionally, the control wafer management system does not work well in minimizing the total number of control wafers needed to properly support the fabrication process.

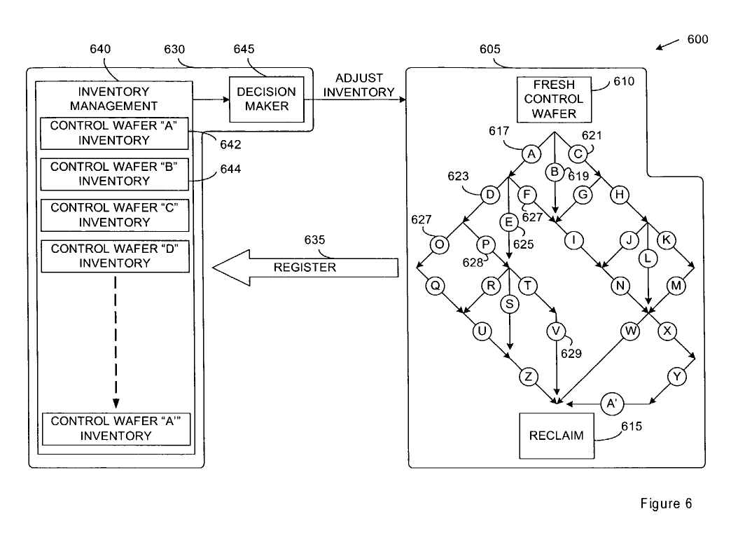

With reference now to FIG. 6, there is shown a diagram illustrating a control wafer management system 600 with an ability to balance control wafer inventory and to minimize control wafer usage, according to a preferred embodiment of the present invention. The control wafer management system 600 may include two components, a control wafer manager 605 that can be similar to the control wafer management system displayed in FIG. 4 and an inventory manager 630. The control wafer manager 605 makes use of a fabrication process dependency graph to permit a single control wafer to be used at several different fabrication process steps. The inventory manager 630 contains an inventory 640 for each step in the fabrication process (for example, control wafer “A” 642 and control wafer “B” 644) and includes a decision maker 645 to decide upon a subsequent fabrication process step for a given control wafer once it has completed a given fabrication process step. Alternatively, the inventory manager 630 may contain an inventory based on control wafer type rather than process step.

According to a preferred embodiment of the present invention, the inventory manager 630 may reside in a computer system (not shown) in the computer's memory (also not shown). The control wafer manager 605 (including a fresh control wafer inventory 610, a reclaim control wafer inventory 615 and a fabrication process dependency graph) may also reside in the computer system's memory. Should control wafer management system 600 be implemented on a computer system (not shown), then the computer system should be able to communicate to machinery, control wafer banks, and so forth located in a fabrication facility so that it will be able to control the movement of the control wafers. Alternatively, the control wafer management system 600 may be a part of a larger IT (information technology) system that is expressly created to manage the operation of a semiconductor fabrication line.

The operation of the control wafer management system 600 may be as follows: a control wafer begins at a fresh control wafer inventory 610, where all control wafers begin. The control wafer then is selected to use in a fabrication process step. For a given control wafer type, a fabrication process dependency graph is used to determine a list of possible next fabrication process steps. For example, using the fabrication process dependency graph displayed in FIG. 6, when a control wafer is in the fresh control wafer inventory 610, the list of possible next fabrication process steps are steps A 617, B 619, and C 621.

Prior to a control wafer being used in a fabrication process step, it may be registered (register 635) with the inventory manager 630. The registration permits the inventory manager 630 to maintain an accurate count of current control wafer inventory. Once the control wafer completes the fabrication process step, it may be registered once again with the inventory manager 630.

After the control wafer completes a fabrication step, the control wafer's next fabrication process step should be determined. The decision maker 645 makes use of the inventory 640 to decide the control wafer's next fabrication process step. For example, if the control wafer has just completed fabrication process step A 617, then the control wafer's next fabrication process step may be one of three fabrication process steps: step D 623, step E 625, or step F 627. Based on this information, the decision maker 645 may check available control inventory for steps D, E, and F. If one of the three steps has a particular control wafer inventory that is less than the other two, then the decision maker 645 may determine the control wafer's next fabrication process step to be that particular fabrication process step. If more than one control wafer inventory is equal and is low, then the decision maker 645 may select a fabrication process step at random. Alternatively, a priority system may be assigned to the fabrication process steps and the decision maker 645 will always assign the control wafer to the fabrication process step with the highest priority if multiple control wafer inventories are equal.

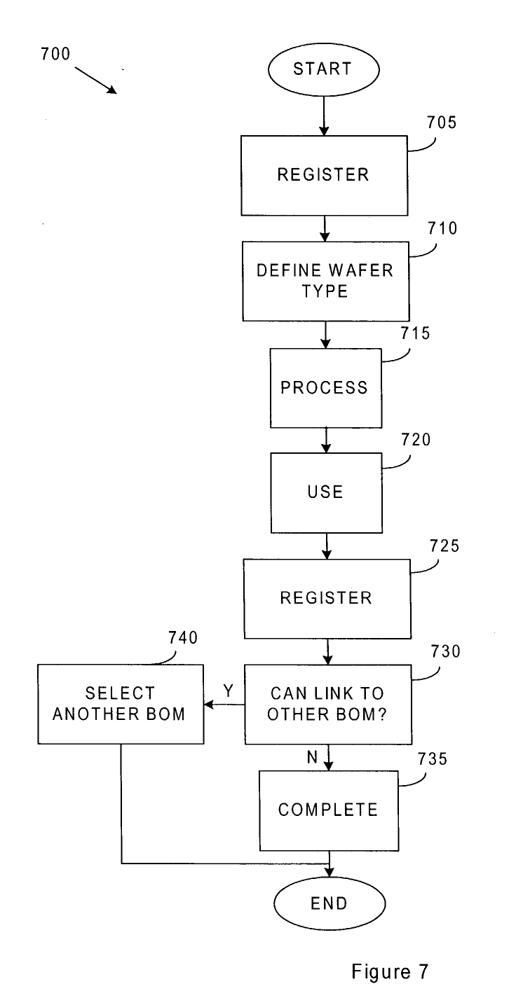

With reference now to FIG. 7, there is shown a flow diagram illustrating a BOM 700 for a single fabrication process step, wherein the BOM has support for balanced control wafer inventory and minimized control wafer usage, according to a preferred embodiment of the present invention. The BOM 700 begins by registering a control wafer being processed with an inventory manager (for example, the inventory manager 630 (FIG. 6)) in block 705. The registering operation allows the inventory manager 630 to keep track of the control wafer being processed. After registration, the BOM 700 defines the type of the control wafer (block 710). For example, if the BOM 700 is associated with fabrication process step C, then the control wafer may be set to control wafer type C.

After having its type defined, the control wafer is prepared for use in the fabrication process step (block 715). After the preparation processing, the control wafer undergoes the fabrication process step (block 720). Once the fabrication process step completes, the control wafer may be examined to determine the performance of the fabrication process step (block 520) and the BOM 700 registers the control wafer with the inventory manager 630 for a second time. The second registering operation notifies the inventory manager 630 that the control wafer has completed processing in its assigned fabrication process step.

The BOM 700 then may check to see if the control wafer may be used in another fabrication process step (link to other BOM, block 730). This can be determined by making reference to a fabrication process dependency graph (such as one displayed in FIG. 6). Given the control wafer's current location (process step), it is possible to determine the next fabrication process step where the control wafer may be able to go. For example (with reference to FIG. 6), if the control wafer is currently at fabrication process step D 623, then the control wafer may be able to be used at fabrication process steps O 627 and P 628. However, if the control wafer is currently at fabrication process step V 629, then the control wafer may not be used at other fabrication process steps and may be sent to be reclaimed (reclaim inventory 615).

If the control wafer can be used at other fabrication process steps, then may be possible to link to other BOMs. To link to another BOM, the BOM 700 sends a request to a decision maker (for example, the decision maker 645 (FIG. 6)) to select another BOM (block 740). The BOM 700 then completes is operation with the current control wafer.

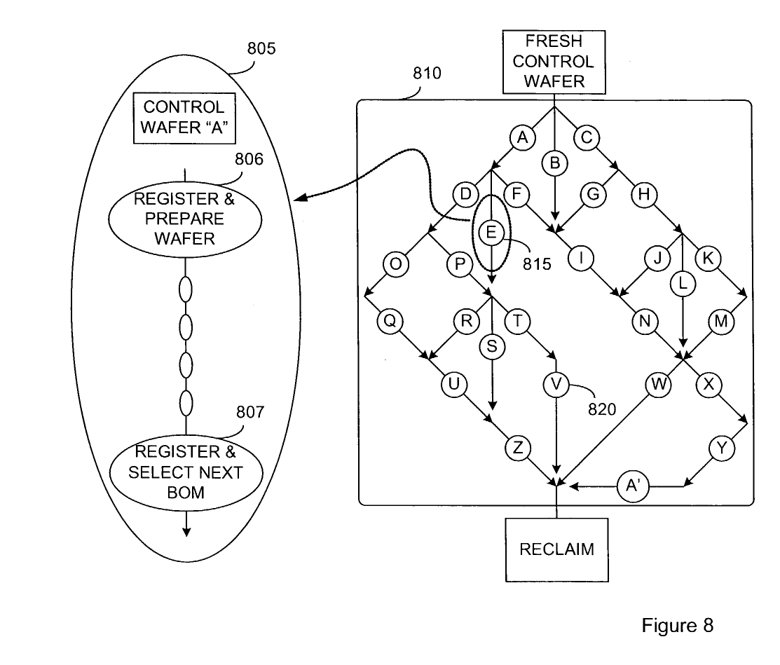

With reference now to FIG. 8, there is shown a diagram illustrating a relationship between a BOM 805 and a fabrication process dependency graph 810, according to a preferred embodiment of the present invention. As discussed earlier, the fabrication process dependency graph 810 is a representation of interdependencies between different steps in the fabrication process. For each fabrication process step (for example, process step E 815) in the fabrication process dependency graph 810, there may be an associated BOM (such as BOM 805). Note that a BOM that is associated with one fabrication process step may be different from another BOM that is associated with a different fabrication process step.

The BOM 805, which is associated with process step E 815, is similar to the BOM 700 discussed in FIG. 7, with an initial registration 806 of a control wafer and a subsequent registration 807 of the control wafer and intermediate process and recipe steps. However, a BOM that is associated with process step V 820, for example, may be quite different. This may be due to the fact that after process step V 820, a control wafer may not be usable for any remaining fabrication process steps and should be reclaimed.

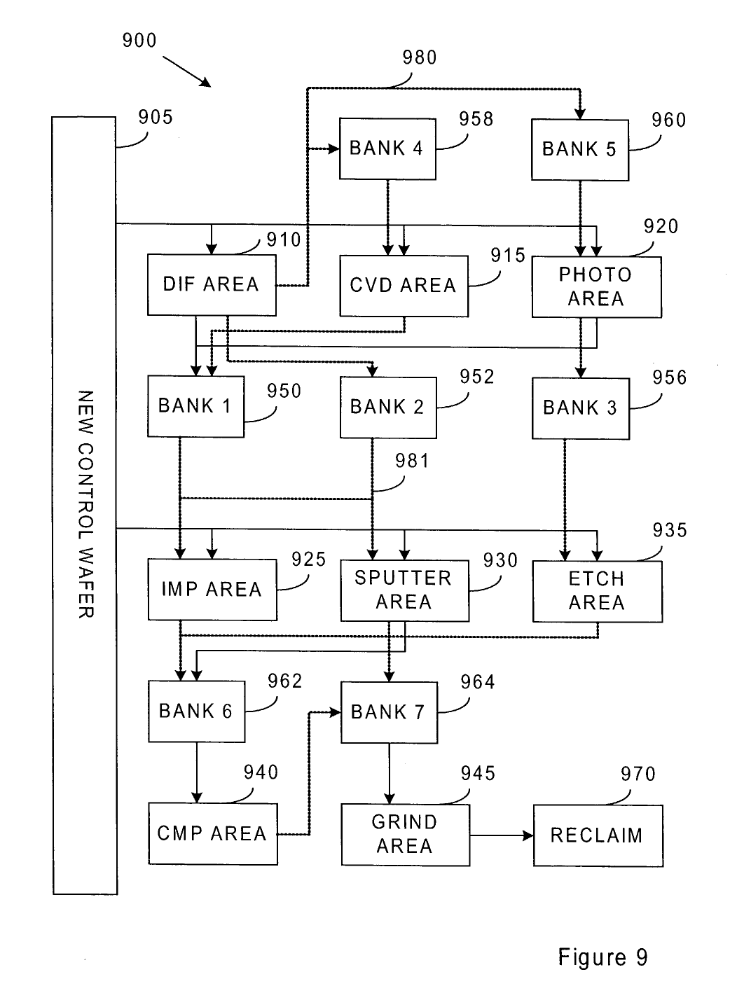

With reference now to FIG. 9, there is shown a diagram illustrating an exemplary fabrication process control flow 900 and the flow of control wafers in the fabrication process, according to a preferred embodiment of the present invention. The fabrication process control flow (control flow) 900 represents an exemplary fabrication process and illustrates the flow of control wafers (not shown) throughout the fabrication process. Note that the control flow 900 represents a single fabrication process and that a different fabrication process will likely have a different control flow.

The control flow 900 may include several different semiconductor wafer fabrication areas, such as but not necessarily limited to: DIF (diffusion) area 910, CVD (chemical vapor deposition) area 915, photo area 920, IMP (implantation) area 925, sputter area 930, etch area 935, CMP (chemical mechanical polish) area 940, and grind area 945. Additionally, the control flow 900 includes a new control wafer inventory 905, a control wafer reclaim inventory 970, and several control wafer banks (such as bank 1 950, bank 2 952, and so forth).

As displayed the new control wafer inventory 905 is connected to six of the eight process areas, with the exception being the CMP and grind areas 940 and 945. This implies that fresh control wafers may be provided to any of the remaining process areas at anytime. Dashed lines, such as dotted line 980 from DIF area 910 to bank 5 960 and dotted line 981 from bank 2 952 to sputter area 930 illustrate the movements of control wafers which have undergone at least one stage of fabrication processing.

A preferred embodiment of the present invention has been successfully implemented in several semiconductor fabrication facilities and savings in control wafer usage have been significant. Control wafer usage has gone from 0.4 control wafers per actual wafer produced down to 0.2 control wafers per actual wafer. This 50 percent savings in control wafer usage has resulted in significant dollar savings as well. For example, if a single fabrication facility produces 40,000 wafers per month, then a savings of 0.2 control wafers per actual wafer would be 8000 control wafers per month. If each control wafer has an estimated cost of 100 dollars, then the savings would be $800,000 per month per fabrication facility.

Although the present invention and its advantages have been described in detail, it should be understood that various changes, substitutions and alterations can be made herein without departing from the spirit and scope of the invention as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for controlling the use of a control wafer comprising:
registering the control wafer a first time;
using the control wafer;
registering the control wafer a second time; and
selecting a second use for the control wafer.

2. The method of claim 1, wherein the first and second registering comprises registering the control wafer with a control wafer inventory.

3. The method of claim 2, wherein there are different control wafer types, and wherein the control wafer inventory is organized by control wafer types.

4. The method of claim 2, wherein the control wafers are used in a fabrication process with a plurality of process steps, and wherein the control wafer inventory is organized by process steps.

5. The method of claim 4, wherein the first registering comprises incrementing an inventory associated with the control wafer.

6. The method of claim 4, wherein the second registering comprises decrementing an inventory associated with the control wafer.

7. The method of claim 1, wherein the using comprises:
preparing the control wafer for a process step; and
processing the control wafer in the process step.

8. The method of claim 1, wherein the selecting comprises:
choosing a second use from a fabrication process dependency graph; and
adding the control wafer to a control wafer list associated with the second use.

9. The method of claim 8, wherein the list is part of a bill of materials (BOM), and the BOM contains processes and recipes for a use to which it is associated.

10. The method of claim 1 further comprising examining the control wafer after the using.

11. A method for minimizing control wafer usage in a fabrication process of a plurality of individual process steps comprising:
registering a control wafer a first time;
using the control wafer;
registering the control wafer a second time;
determining a list of possible subsequent process steps; and
selecting a subsequent process step from the list of possible subsequent process steps.

12. The method of claim 11, wherein an inventory is maintained for control wafers at each process step in the fabrication process, and wherein the selecting comprises:
determining a number of control wafers at each process step in the list of possible subsequent process steps; and
selecting a process step with the smallest number of control wafers.

13. The method of claim 12, wherein a plurality of process steps in the list of possible subsequent process steps have both the smallest number of control wafers and an equal number of control wafers, and wherein the subsequent process step is selected at random from the plurality of process steps with an equal number of control wafers.

14. The method of claim 12, wherein each individual process step is assigned a priority number, wherein a plurality of process steps in the list of possible subsequent process steps have both the smallest number of control wafers and an equal number of control wafers, and wherein the subsequent process step is the process step with the highest priority number from the plurality of process steps with an equal number of control wafers.

15. A system for controlling the use of a control wafer comprising:
a control wafer manager with circuitry to maintain an inventory of fresh control wafers, an inventory of reclaimed control wafers, and a fabrication process dependency graph; and
an inventory manager coupled to the control wafer manager, the inventory manager containing circuitry to maintain an inventory of control wafers used in a fabrication process.

16. The system of claim 15, wherein the inventories of fresh and reclaimed control wafers contain unique identifiers for every control wafer.

17. The system of claim 15, wherein there is a plurality of control wafer types, and wherein the inventories of fresh and reclaimed control wafers contain unique identifiers for every type of control wafer.

18. The system of claim 17, wherein the inventories of fresh and reclaimed control wafers also contain a control wafer count for each type of control wafer.

19. The system of claim 15, wherein the inventory manager further comprises a decision maker unit having an input coupled to the inventory of control wafers and an output coupled to the control wafer manager, the decision maker unit containing circuitry to select a subsequent fabrication process step for a control wafer that has completed its current fabrication process step.

20. The system of claim 19, wherein there may be more than one possible subsequent fabrication process step, and wherein the decision maker unit uses an inventory of control wafers for each of the possible subsequent fabrication process steps and selects the subsequent fabrication process step with the fewest number of control wafers in its inventory.

21. The system of claim 20, wherein if there is more than one possible subsequent fabrication process step with a minimum number of control wafers and with the same number of control wafers, then the decision maker unit selects a subsequent fabrication process step at random out of the set of possible subsequent fabrication process steps with the same number of control wafers.

22. The system of claim 21, wherein fabrication process steps are assigned a priority number, and wherein if there is more than one possible subsequent fabrication process step with a minimum number of control wafers and the same number of control wafers, then the decision maker unit selects a subsequent fabrication process step with a higher priority.
